(19) United States
(12) Patent Application Publication
(10) Pub. No.: US 2008/0315376 A1
(43) Pub. Date: Dec. 25, 2008

(54) Conformal EMI shielding with enhanced reliability

(76) Inventors: Jinbang Tang, Chandler, AZ (US); Jong-Kai Lin, Chandler, AZ (US)

Correspondence Address: HAMILTON & TERRILE, LLP - FREESCALE, P.O. BOX 203518, AUSTIN, TX, 78720, US

(21) Appl. No.: 11/764,911

(22) Filed: Jun. 19, 2007

(51) Int. Cl. H01L 23/552; H01L 21/56

(52) U.S. Cl. 257/660; 438/127; 257/E23.114; 257/E21.504

(57) ABSTRACT

An electromagnetic interference (EMI) and/or electromagnetic radiation shield is formed on a plurality of encapsulated modules by attaching a molded package panel to a process carrier (10) using a double side adhesive tape (12) before singulating the individual modules without separating them from the double side adhesive tape. By forming a conductive layer (50) over a mold encapsulant (16) and on the sidewalls of grooves (40-47) that are cut through the mold encapsulant (16) and underlying circuit substrate (14), the conductive layer (50) may be electrically coupled to one or more conductive connection pads (61-66) by virtue of the placement of the conductive connection pads at the periphery or side of the circuit substrate (14).

### BACKGROUND OF THE INVENTION

1. Field of the Invention

The present invention is directed in general to the field of semiconductor devices. In one aspect, the present invention relates to semiconductor packaging devices which are shielded to protect against electromagnetic interference (EMI).

2. Description of the Related Art

Semiconductor devices need to be protected from electromagnetic interference (EMI) which is the undesired electrical signals, or noise, in electronic system circuitry caused by the unintentional coupling of electromagnetic field energy from other circuitry, such as wires, printed circuit board conductors, connector elements, connector pins, cables, and the like. For example, multiple chip modules (MCM) are semiconductor devices having a plurality of discrete microelectronic devices (e.g., a processor unit, memory unit, related logic units, resistors, capacitors, inductors, and the like) that are connected together on a single MCM substrate. Conventional approaches for shielding against EMI have used board or system level EMI shielding techniques, though this does not provide protection against interference caused by modules within the board or system. Other shielding techniques have attempted to protect against radio/electromagnetic interference by using conformal shielding technologies to packaging the individual circuit modules (e.g., MCMs), such as by using wire bond grounding connection techniques, laser-drilled via grounding connection techniques, or double-cutting methods. However, these techniques require extra substrate space to apply the shielding, or impose an extra space and double saw operation, or otherwise increase the cost and complexity of the packaging process.

Accordingly, there exists a need for a packaging scheme that provides improved EMI shielding at the module level. In addition, there is a need for a cost effective semiconductor device package that provides reliable EMI shielding with little or no impact on the size of the packaging device. There is also a need for improved packaging processes and devices to overcome the problems in the art, such as outlined above. Further limitations and disadvantages of conventional processes and technologies will become apparent to one of skill in the art after reviewing the remainder of the present application with reference to the drawings and detailed description which follow.

### BRIEF DESCRIPTION OF THE DRAWINGS

The present invention may be understood, and its numerous objects, features and advantages obtained, when the following detailed description is considered in conjunction with the following drawings, in which:

FIG. 1 is a cross-sectional view of a plurality of chip modules (panel) which are encapsulated with a molding compound and mounted on a process carrier substrate and a layer of double-sided tape or attachment chemical;

FIG. 2 illustrates a perspective view of the encapsulated plurality of chip modules (panel) depicted in FIG. 1;

FIG. 3 illustrates processing subsequent to FIG. 1 with a cross-sectional view of the encapsulated plurality of chip modules (panel) after cutting lines are cut down through the molding compound and circuit substrate and into the double sided tape;

FIG. 4 illustrates a perspective view of the encapsulated plurality of chip modules (panel) depicted in FIG. 3;

FIG. 5 illustrates processing subsequent to FIG. 3 with a cross-sectional view of the encapsulated plurality of chip modules after a conductive shielding layer is formed over the molding compound;

FIG. 6 illustrates processing subsequent to FIG. 5 with a cross-sectional view of the encapsulated plurality of chip modules after the double-sided tape and process carrier is removed;

FIG. 7 illustrates a perspective view of one of the individual encapsulated chip modules depicted in FIG. 6; and

FIG. 8 illustrates a sample fabrication sequence flow for fabricating chip modules with a conformal EMI shielding.

It will be appreciated that for simplicity and clarity of illustration, elements illustrated in the drawings have not necessarily been drawn to scale. For example, the dimensions of some of the elements are exaggerated relative to other elements for purposes of promoting and improving clarity and understanding. Further, where considered appropriate, reference numerals have been repeated among the drawings to represent corresponding or analogous elements.

### DETAILED DESCRIPTION

A method and apparatus are described for fabricating a shielded encapsulated semiconductor device or devices. As a preliminary step, a package panel is assembled by mounting a plurality of devices onto a circuit substrate and then encapsulating the plurality of devices with a molding compound. The package panel is then mounted on a process carrier by using a removable attachment device, such as a thick double-sided tape or chemical attachment layer, to adhere the package panel to the process carrier. Once mounted, the package panel is singulated or cut using any desired saw or cutting process, such as laser cutting. By cutting through the molding compound and circuit substrate and into the attachment device, grooves are formed between the individual chip modules all the way down into the attachment device. After the grooves are formed, a shielding material cover layer is conformally formed over the molding compound and in the grooves (e.g., by sputtering, spraying, etc.), thereby making electrical contact with grounding pad structures formed in the circuit substrate. By properly designing the grounding pad structures and locating them in the circuit substrate in alignment with the cutting lines, a solid and reliable grounding connection is established between the grounding pad structures and the shielding layer. In selected embodiments, the grounding pad structure(s) may be connected with a ground ring.

Various illustrative embodiments will now be described in detail with reference to the accompanying figures. While various details are set forth in the following description, it will be appreciated that the present invention may be practiced without these specific details, and that numerous implementation-specific decisions may be made to the invention described herein to achieve the device designer's specific goals, such as compliance with process technology or design-related constraints, which will vary from one implementation to another. While such a development effort might be complex and time-consuming, it would nevertheless be a routine undertaking for those of ordinary skill in the art having the benefit of this disclosure. For example, selected aspects are depicted with reference to simplified cross sectional drawings of a semiconductor device without including every device feature or geometry in order to avoid limiting or obscuring the present invention. It is also noted that, throughout this detailed description, certain materials will be formed and removed to fabricate the semiconductor structure. Where the specific procedures for forming or removing such materials are not detailed below, conventional techniques to one skilled in the art for growing, depositing, removing or otherwise forming such layers at appropriate thicknesses shall be intended. Such details are well known and not considered necessary to teach one skilled in the art of how to make or use the present invention.

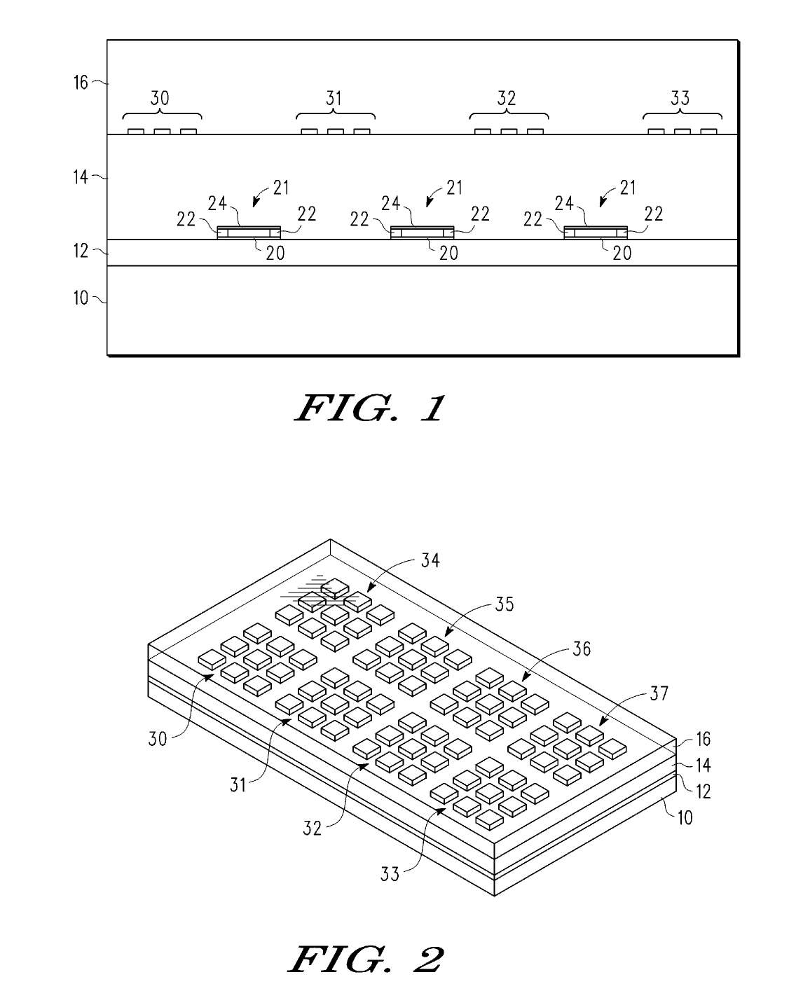

Turning now to FIG. 1, a cross-sectional view is illustrated of a plurality of module panels 30-33 which are mounted or attached on a circuit substrate 14. In addition, FIG. 2 is provided to illustrate a perspective exterior view of the encapsulated plurality of chip modules depicted in FIG. 1. As illustrated, each chip module (e.g., 30) includes a plurality of microelectronic devices (e.g., a processor unit, memory unit, related logic units, resistors, capacitors, inductors, and the like), though it will be appreciated that the advantages of the present invention may also be obtained if each chip module includes only a single microelectronic device. Each microelectronic device in the chip module may be mounted or attached to the circuit substrate 14 using surface mount techniques, including, but not limited to wire bond, tape-automated bond, solder ball connectors, flip-chip bonding, etc. For example, each microelectronic device may have die bond pads (not shown) which are electrically connected to landing pads (not shown) on the circuit substrate, such as by using wire bonds.

At the circuit substrate 14, conductive paths are formed between upper and lower surfaces of the circuit substrate 14 to electrically couple signals and/or voltages to and from the chip module. Thus, the circuit substrate 14 may be formed to any desired shape and thickness, and may include any desired features for use in forming a functional semiconductor package. In addition, the circuit substrate 14 may be fabricated with any desired material, such as a relatively thin, flexible film of an electrically insulative material (such as an organic polymer resin), or a rigid, substantially planar member fabricated from any known, suitable materials, including, but not limited to, insulator-coated silicon, a glass, a ceramic, an epoxy resin, bismaleimide-triazine (BT) resin, or any other material known in the art to be suitable for use as a circuit substrate.

In selected embodiments, the circuit substrate 14 is formed to include a plurality of grounding pad structures 21 which are designed and positioned to provide a robust connection path between the EMI shielding layer (described hereinbelow) and a ground or reference voltage lead for each individual chip module. The design and placement of the grounding pad structures may be located at any depth in the circuit substrate 14, though they should be located in alignment with the cutting lines (described hereinbelow) to promote a solid and reliable grounding connection between the grounding pad structures and the shielding layer. In addition, by positioning the grounding pad structures on the bottom of the circuit substrate 14, no shielding ring is needed in the circuit substrate to protect against electromagnetic interference that would otherwise impinge from the side of the circuit substrate. The quality of the grounding connection may be enhanced by forming the grounding pad structures from one or more connection pad layers. For example, FIG. 1 shows that each grounding pad structure 21 includes a lower pad layer 20, an upper pad layer 24 and a connection via 22 that electrically connects the lower and upper pad layers 20, 24. By using a plurality of grounding pad layers, potential problems with corner contact issues are reduced or eliminated, thereby providing an enhanced connection to the subsequently formed shield layer.

As further illustrated in FIGS. 1 and 2, the plurality of chip modules 30-37 are encapsulated with an insulating package body or molding 16 which may be formed by applying, injecting or otherwise forming an encapsulant to seal and protect the microelectronic devices in the chip modules from moisture, contamination, corrosion, and mechanical shock. For example, after wire bonding or electrically coupling the microelectronic devices 30-37 to the circuit substrate 14, an encapsulation process is performed to cover the chip modules with a mold compound or mold encapsulant. The mold encapsulant may be a silica-filled resin, a ceramic, a halide-free material, or some other protective encapsulant layer. The mold encapsulant is typically applied using a liquid, which is then heated to form a solid by curing in a UV or ambient atmosphere. The encapsulant can also be a solid that is heated to form a liquid and then cooled to form a solid mold over the lead frame. As will be appreciated, any desired encapsulant process may be used.

Once the plurality of chip modules 30-33 are mounted on a circuit substrate 14 and encapsulated with a molding compound 16, the assembled package panel is mounted on a process carrier 10 with a removable attachment device 12. The purpose of the removable attachment device 12 is to secure the encapsulated chip modules 30-33 during the subsequent singulation process so that a shielding material may be conformally applied to exterior surfaces of the separated encapsulated chip modules. With this purpose in mind, any desired attachment technique may be used to implement the removable attachment device 12, including but not limited to applying a thick double-sided tape, glue layer or other removable die attach material between the lower surface of the circuit substrate and the process carrier 10.

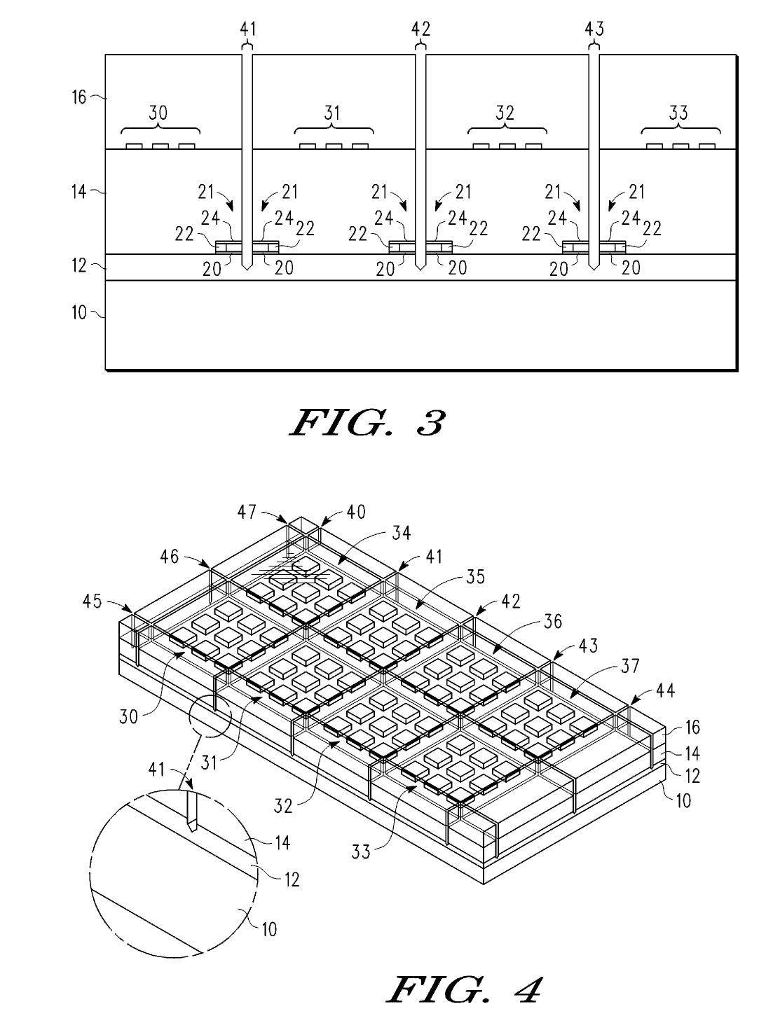

After the assembled package panel is mounted on the process carrier 10 with a removable attachment device 12, the insulating package body 16 and circuit substrate 14 are cut. This is depicted in FIG. 3 which illustrates processing subsequent to FIG. 1 with a cross-sectional view of the encapsulated plurality of chip modules after cutting lines 40-47 are cut down through the molding compound 16 and circuit substrate 14 and into the double sided tape 12. In addition, FIG. 4 is provided to illustrate a perspective exterior view of the encapsulated plurality of chip modules depicted in FIG. 3. As illustrated in FIGS. 3 and 4, the cuts into the insulating package body 16 and circuit substrate 14 form grooves 40-47 which separate the chip modules 30-37 mounted on the circuit substrate 14. The grooves 40-43 are shown in FIG. 3 as having vertical sidewalls that are separated by a predetermined minimum distance sloped so that a conductive shielding layer may be separately deposited on both sidewalls during subsequent processing. However, it will be appreciated that the grooves may instead have angled sidewalls which may facilitate the deposition of the conductive shielding layer, though at the expense of consuming valuable real estate. The cut may be made with a saw having a cutting blade, a laser, or any other instrument that can segregate or singulate the chip modules 30-37. Preferably, the cutting instrument provides a depth cut that is greater than the combined height of the insulating package body 16 and circuit substrate 14 so that the groove extends into the attachment device 12, as illustrated with the enlarged cross-section shown in FIG. 4. In this way, the shielding layer subsequently formed in the grooves will completely encapsulate the singulated modules. The formation of the shielding layer may be facilitated by using a cutting instrument that forms a V-shaped cut for the entire groove (not shown) since this shape is easier to cover with the conductive shielding layer. With such a cut, the groove is wider at the top of the mold compound and narrower at the bottom where it terminates in the removable attachment device 12. In addition, by controlling the cutting action so that the grooves terminate in the removable attachment device 12, the position of the individual chip modules 31-37 in relation to the process circuit 10 is maintained by virtue of the adhesive function provided by the removable attachment device 12, which helps facilitate subsequent handling or processing of the individual chip modules.

By cutting all the way down to the attachment device 12, it is important to position and align the cut lines so that the cuts do not intersect with the microelectronic devices in the chip modules 30-37. This is illustrated in FIG. 3, where each groove (e.g., groove 41) is positioned between the chip modules (e.g., modules 30 and 31). In addition, the positioning and alignment of the cut lines should be controlled so there is no unintentional intersection with any conductive paths formed in the circuit substrate 14. As will be appreciated, such an intersection should ordinarily be avoided to prevent a short between the conductive path and the conductive shield layer subsequently formed on the groove sidewalls. However, in selected embodiments of the present invention, the positioning and alignment of the grooves may be deliberately controlled to intersect with the grounding pad structures 21 formed in the circuit substrate 14. This is illustrated in FIG. 3 where each of the grooves 41-43 is positioned to intersect with the grounding pad structures 21. This positioning allows a direct electrical connection to be established between such an intersection should ordinarily be avoided to prevent a short between the grounding pad structures 21 in the circuit substrate 14 and the conductive shield layer subsequently formed on the groove sidewalls.

FIG. 5 illustrates processing subsequent to FIG. 3 with a cross-sectional view of the encapsulated plurality of chip modules 31-33 after a conductive shielding layer 50 is formed over the molding compound 16 and side of the circuit substrate 14. The conductive shielding layer 42 can be a polymer, metal, metal alloy (such as a ferromagnetic or ferroelectric material), ink, paint, the like or combinations of the above. In one embodiment, the conductive shielding layer is formed from aluminum (Al), copper (Cu), nickel iron (NiFe), tin (Sn), zinc (Zn), or the like, including any combination of one or more of the foregoing. For example, by forming the conductive shielding layer 50 as a combination of a non-ferromagnetic material and ferromagnetic material (e.g., a layer of copper and a layer of NiFe), then the circuit modules are protected from electromagnetic fields that are both electric and magnetic with a electromagnetic or broadband shield. Prior to depositing the conductive shielding layer 50, the upper surface of the mold compound 16 and the groove sidewalls (on both the mold compound and circuit substrate portions) may be prepared so that the conductive shielding layer 50 will adhere. The conductive shielding layer 50 can be deposited by physical vapor deposition (PVD), chemical vapor deposition (CVD), atomic layer deposition (ALD), electrolytic plating, electroless plating, flame spray, conductive paint spray, vacuum metallization, pad printing, sputtering, evaporation, dispensing, spray coating, or the like, including any combination of one or more of the foregoing. The conductive shielding layer 50 may be formed on each groove sidewall to a thickness of approximately 1 to 50 microns in thickness, though different thicknesses may be used depending on the shielding effectiveness desired. The minimum thickness of the conductive shielding layer 50 depends on the process used to form the conductive shielding layer 50, while the maximum thickness depends on the amount of stress of the conductive shielding layer 50, as well as the minimum spacing dimension 51-53 required for each groove after the conductive shielding layer 50 is applied.

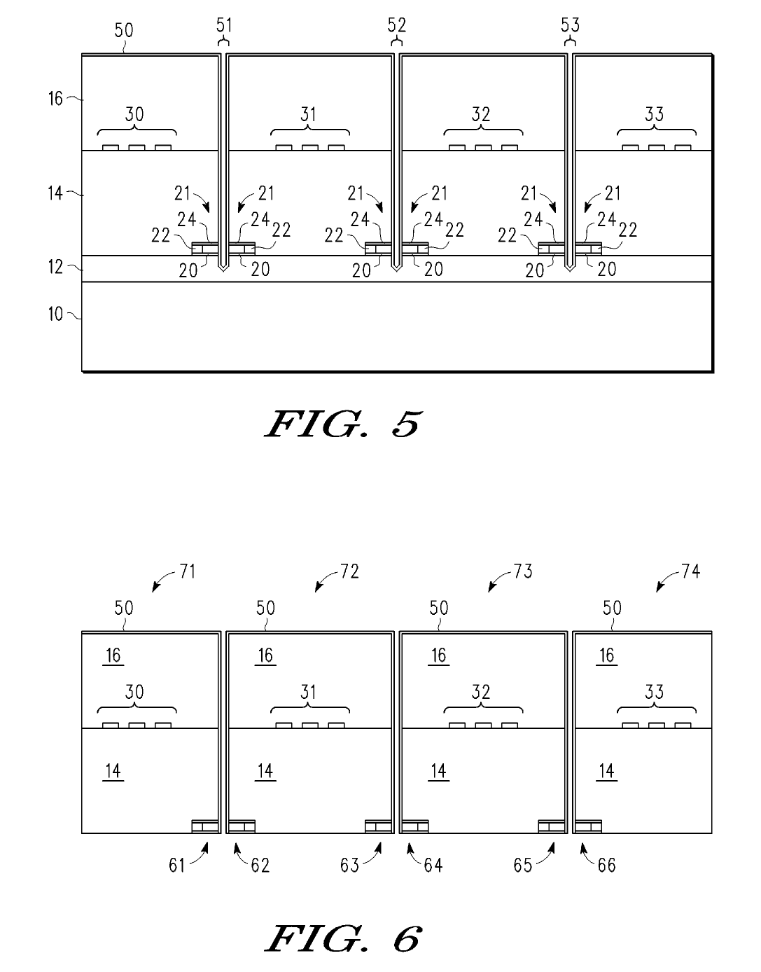

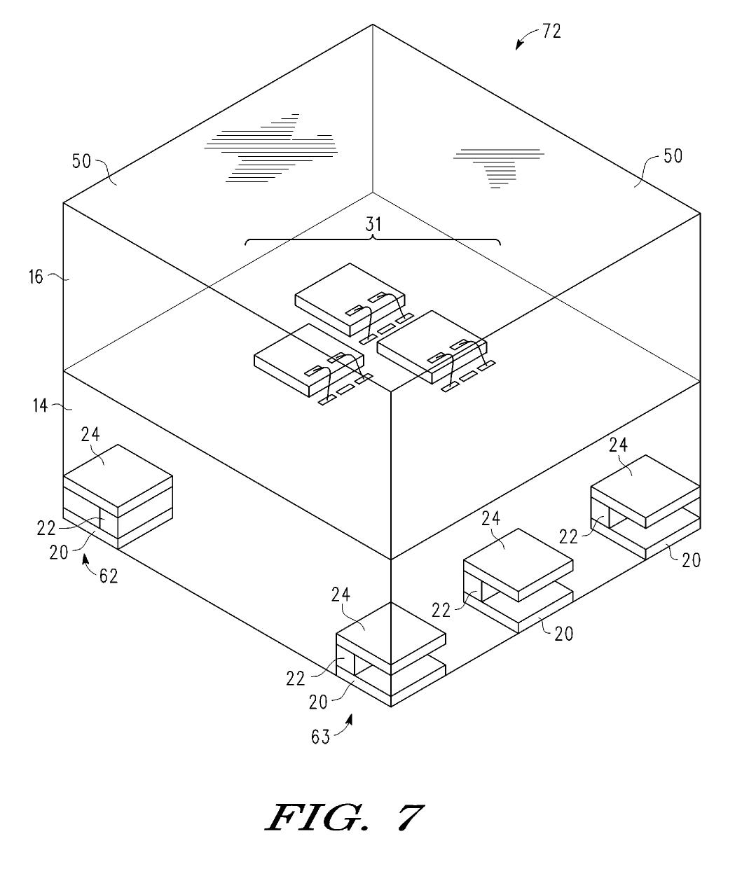

After the conductive shielding layer 50 is deposited or applied, the encapsulated modules are separated from one another into individual encapsulated modules 71-74 by removing them from the removable attachment device 12. This is illustrated in FIG. 6 which illustrates processing subsequent to FIG. 5 with a cross-sectional view of the encapsulated plurality of chip modules after the double-sided tape 12 and process carrier 10 are removed. In addition, FIG. 7 is provided to illustrate a perspective exterior view of one of the individual encapsulated chip modules 72 depicted in FIG. 6. Having previously cut through the insulating package body 16 and circuit substrate 14, there is no additional cutting or singulation necessary, and the fabrication process is accordingly simplified. As shown in FIG. 6, each individual encapsulated module 71-74 has one or more grounding pad structures 61-66 located at the periphery of the circuit substrate 14, each of which is electrically connected to the conductive shielding layer 50 formed on the exterior of the module. While the cross-sectional view of FIG. 6 shows only two grounding pad structures 62, 63, it will be appreciated that there can be additional grounding pad structures on each module, as illustrated in the perspective view of FIG. 7. Once singulated, the external coating of the conductive shield layer 50 is electrically coupled to a reference voltage (e.g., ground) by way of the grounding pad structures (e.g., 62-63) to form an EMI or electromagnetic shield.

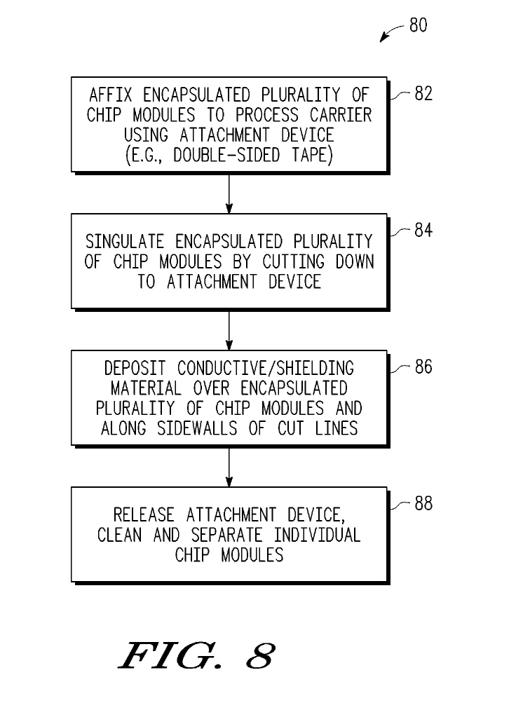

Turning now to FIG. 8, there is illustrated a sample fabrication sequence flow 80 for fabricating chip modules with a conformal EMI shielding. As an initial step 82, a plurality of chip modules mounted on the surface of a circuit substrate or printed circuit board using any desired surface mount technology, encapsulated with an encapsulation packaging, and affixed to a process carrier using an attachment device, such as a double sided tape or glue layer. With the encapsulated chip modules assembled on a package panel, the encapsulated plurality of chip modules are marked and singulated by cutting down to the removable attachment device (step 84), but the singulated chip modules remain affixed to the process carrier by the attachment device. The grooves formed by the cuts expose one or more connection pads or rings formed in the circuit substrate. A conductive/shielding material is deposited over encapsulated plurality of chip modules and along sidewalls of grooves (step 86) using any desired technique, such as plating, sputtering, spraying, etc. As deposited, the conductive shield layer makes contact with the exposed connection pads to form a conformal EMI shield by virtue of being electrically coupled through the connection pad to a reference voltage (e.g., ground). Once the conductive shielding layer is formed, the removable attachment device is released, and the individual chip modules are cleaned and separated from one another (step 88).

In one form, there is provided herein a method for making a package assembly with conformal EMI shielding. As disclosed, a circuit substrate having first and second surfaces is provided, where microelectronic devices are attached to the first surface of the circuit substrate and encapsulated with an encapsulation package. A process carrier is attached to the second surface of the circuit substrate using a removable attachment device, such as a double-sided tape or glue layer. Subsequently, the encapsulated microelectronic devices are singulated by cutting through the encapsulation package and the circuit substrate and into the removable attachment device, such as by performing a saw or laser cut. The cutting action forms grooves to separate a first encapsulated microelectronic circuit from a second encapsulated microelectronic circuit. Once the grooves are cut, a conductive layer is formed over the encapsulation package and on sidewalls of the grooves, thereby coating the first and second encapsulated microelectronic circuits. At this point, the removable attachment device may be detached or removed from the circuit substrate to thereby separate the first and second encapsulated microelectronic circuits. When the circuit substrate is provided with a plurality of connection pads formed therein, the cutting is controlled to form a plurality of grooves, where each groove intersects with one of the plurality of connection pads, where each connection pad may be formed from one or more conductive pad layers that are electrically connected together and to the conductive layer when formed on the sidewalls of the plurality of grooves.

In another form, there is provided semiconductor package having a circuit substrate with top, bottom and side surfaces and with one or more conductive connection pads formed at a side surface. One or more connection pads are formed in the circuit substrate and are located at one of the side surfaces of the circuit substrate so as to be electrically connected to the conductive layer formed on the side surfaces of the circuit substrate. In selected embodiments, each connection pad may be formed from a plurality of conductive pads formed in the circuit substrate which are electrically connected together by a connection via, and which are electrically connected to a reference voltage by one or more conductors. The semiconductor package also includes one or more microelectronic circuits that are attached to the top surface of the circuit substrate, as well as an encapsulant package (e.g., mold compound) formed over the top surface of the circuit substrate to encapsulate the one or more microelectronic circuits. In addition, a conductive layer is formed on the top and side surfaces of the encapsulant package and on the side surfaces of the circuit substrate such that the conductive layer is electrically coupled to the one or more conductive connection pads. By forming the conductive layer with a conductive metal or polymer material that completely covers the top and side surfaces of the encapsulant package and the side surfaces of the circuit substrate, the conductive layer provides EMI shielding for the microelectronic circuits.

In yet another form, there is provided a method of forming a semiconductor package wherein a package panel is provided that includes a plurality of circuit devices attached to a circuit substrate and encapsulated with a mold encapsulant. In an example embodiment, the package panel is provided by attaching a plurality of circuit devices to a circuit substrate, and then encapsulating the plurality of circuit devices with a mold encapsulant. The package panel is attached to a process carrier by applying a removable attachment device (e.g., a double-sided tape or chemical attachment layer). Once attached to the process carrier, the package panel is separated into a plurality of chip modules without removing the plurality of chip modules from the removable attachment device. This is done by cutting through the mold encapsulant and circuit substrate and into the removable attachment device (e.g., by performing a saw cut or laser cut) to form a plurality of grooves that separate the plurality of chip modules. In selected embodiments, each circuit substrate includes connection pads formed therein such that the cutting through the mold encapsulant and circuit substrate and into the removable attachment device forms a plurality of grooves, where each groove intersects with one of the connection pads. Subsequently, a conductive layer is formed over the mold encapsulant and on sidewalls of the grooves so as to coat the top and sides of each chip module. For example, by depositing a conductive layer that completely covers top and side surfaces of the mold encapsulant and side surfaces of the circuit substrate, the conductive layer provides EMI shielding. Once the conductive layer is applied, the chip modules may be separated from the removable attachment device.

Although the described exemplary embodiments disclosed herein are directed to various packaging assemblies and methods for making same, the present invention is not necessarily limited to the example embodiments which illustrate inventive aspects of the present invention that are applicable to a wide variety of packaging processes and/or devices. Thus, the particular embodiments disclosed above are illustrative only and should not be taken as limitations upon the present invention, as the invention may be modified and practiced in different but equivalent manners apparent to those skilled in the art having the benefit of the teachings herein. Accordingly, the foregoing description is not intended to limit the invention to the particular form set forth, but on the contrary, is intended to cover such alternatives, modifications and equivalents as may be included within the spirit and scope of the invention as defined by the appended claims so that those skilled in the art should understand that they can make various changes, substitutions and alterations without departing from the spirit and scope of the invention in its broadest form.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

What is claimed is:

1. A method for making a package assembly with conformal EMI shielding, comprising:
providing a circuit substrate having first and second surfaces;
attaching a plurality of microelectronic devices to the first surface of the circuit substrate;
encapsulating the plurality of microelectronic devices by forming an encapsulation package on the first surface of the circuit substrate;
attaching a process carrier to the second surface of the circuit substrate using a removable attachment device;
cutting through the encapsulation package and circuit substrate and into the removable attachment device, thereby forming a groove to separate a first encapsulated microelectronic circuit from a second encapsulated microelectronic circuit;
forming a conductive layer over the encapsulation package and on sidewalls of the groove, thereby coating the first and second encapsulated microelectronic circuits; and
removing the removable attachment device from the circuit substrate to thereby separate the first and second encapsulated microelectronic circuits.

2. The method of claim 1, where attaching the process carrier to the second surface of the circuit substrate comprises applying a double-sided tape layer to attach the process carrier to the second surface of the circuit substrate.

3. The method of claim 1, where attaching the process carrier to the second surface of the circuit substrate comprises applying a glue layer to attach the process carrier to the second surface of the circuit substrate.

4. The method of claim 1, where cutting through the encapsulation package and circuit substrate comprises performing a saw cut through the encapsulation package and circuit substrate and into the removable attachment device.

5. The method of claim 1, where cutting through the encapsulation package and circuit substrate comprises performing a laser cut through the encapsulation package and circuit substrate and into the removable attachment device.

6. The method of claim 1, where forming a conductive layer comprises depositing a conductive layer by physical vapor deposition, chemical vapor deposition, atomic layer deposition, electrolytic plating, electroless plating, flame spray, conductive paint spray, vacuum metallization, pad printing, sputtering, evaporation, dispensing or spray coating.

7. The method of claim 1, where providing a circuit substrate comprises providing a circuit substrate having a plurality of connection pads formed therein such that the cutting through the encapsulation package and circuit substrate and into the removable attachment device forms a plurality of grooves, where each groove intersects with one of the plurality of connection pads.

8. The method of claim 7, where each connection pad comprises a first conductive pad layer and a second conductive pad layer that are electrically connected together and to the conductive layer when formed on the sidewalls of the plurality of grooves.

9. A semiconductor package comprising:
a circuit substrate having top, bottom and side surfaces, where one or more conductive connection pads are formed at a side surface;
one or more microelectronic circuits attached to the top surface of the circuit substrate;
an encapsulant package formed over the top surface of the circuit substrate to encapsulate the one or more microelectronic circuits, said encapsulant package having top and side surfaces; and
a conductive layer formed on the top and side surfaces of the encapsulant package and on the side surfaces of the circuit substrate such that the conductive layer is electrically coupled to the one or more conductive connection pads.

10. The semiconductor package of claim 9, where the circuit substrate comprises at least one connection pad formed therein and located at one of the side surfaces of the circuit substrate so as to be electrically connected to the conductive layer formed on the side surfaces of the circuit substrate.

11. The semiconductor package of claim 10, where the at least one connection pad comprises a plurality of conductive pads formed in the circuit substrate and electrically connected together by a connection via.

12. The semiconductor package of claim 9, where the circuit substrate comprises one or more conductors for electrically connecting the at least one connection pad to a reference voltage.

13. The semiconductor package of claim 9, where the encapsulant package comprises a mold compound.

14. The semiconductor package of claim 9, where the conductive layer comprises a conductive metal or polymer material that completely covers the top and side surfaces of the encapsulant package and the side surfaces of the circuit substrate to provide EMI shielding.

15. A method of forming a semiconductor package comprising:
providing a package panel comprising a plurality of circuit devices attached to a circuit substrate and encapsulated with a mold encapsulant;
applying a removable attachment device to attach the package panel to a process carrier;
separating the package panel into a plurality of chip modules without removing the plurality of chip modules from the removable attachment device by cutting through the mold encapsulant and circuit substrate and into the removable attachment device to form a plurality of grooves that separate the plurality of chip modules;
forming a conductive layer over the mold encapsulant and on sidewalls of the grooves; and
separating the plurality of chip modules from the removable attachment device.

16. The method of claim 15, where providing a package panel comprises:
providing a circuit substrate;
attaching a plurality of circuit devices to the circuit substrate; and
forming a package panel by encapsulating the plurality of circuit devices with a mold encapsulant.

17. The method of claim 15, where applying a removable attachment device comprises attaching the process carrier to the circuit substrate with a double-sided tape or chemical attachment layer.

18. The method of claim 15, where forming a conductive layer comprises depositing a conductive layer that completely covers top and side surfaces of the mold encapsulant and side surfaces of the circuit substrate to provide EMI shielding.

19. The method of claim 15, where providing a package panel comprises providing a circuit substrate having a plurality of connection pads formed therein such that the cutting through the mold encapsulant and circuit substrate and into the removable attachment device forms a plurality of grooves, where each groove intersects with one of the plurality of connection pads.

20. The method of claim 15, where cutting through the encapsulation package and circuit substrate comprises performing a saw cut or laser cut through the mold encapsulant and circuit substrate and into the removable attachment device.
